(19) United States
(12) Patent Application Publication
(10) Pub. No.: US 2010/0044584 A1
(43) Pub. Date: Feb. 25, 2010

(54) CARBON NANOTUBE CONTAINING MATERIALS AND ARTICLES CONTAINING SUCH MATERIALS FOR ALTERING ELECTROMAGNETIC RADIATION

(75) Inventors: Christopher H. Cooper, Windsor, VT (US); William K. Cooper, Santa Fe, NM (US); Alan G. Cummings, Hartland, VT (US)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Seldon Technologies LLC,

(21) Appl. No.: 12/350,036

(22) Filed: Jan. 7, 2009

Related U.S. Application Data
(63) Continuation of application No. 10/884,919, filed on Jul. 7, 2004, now abandoned.
(60) Provisional application No. 60/485,117, filed on Jul. 8, 2003.

(51) Int. Cl. B01J 19/12; D01F 9/12; C04B 35/44; C04B 35/547; C04B 35/553; C04B 35/48; C04B 35/50; C30B 29/00; C03C 14/00; C04B 35/563; C04B 35/565; C08K 3/04; C09K 11/06; B32B 9/00

(52) U.S. Cl. 250/459.1; 423/447.2; 501/153; 501/154; 501/151; 501/134; 501/152; 501/86; 501/32; 501/87; 501/90; 524/496; 252/301.16; 428/367; 250/492.1; 977/742; 977/750; 977/752

(57) ABSTRACT

Disclosed herein is a material for altering electromagnetic radiation incident on the material. The material disclosed herein comprises carbon nanotubes having a length (L) that meets the following formula (1):

L≧½ λ (1)

where λ is the wavelength of the electromagnetic radiation incident on the material. Also disclosed herein are methods of altering electromagnetic radiation, including mitigating, intensifying, or absorbing and re-transmitting electromagnetic radiation using the disclosed material.

This application claims the benefit of domestic priority to U.S. Provisional Patent Application No. 60/485,117, filed Jul. 8, 2003, which is herein incorporated by reference in its entirety.

Disclosed herein is a material comprising carbon nanotubes for altering electromagnetic radiation incident on the material. Also disclosed herein are methods of altering electromagnetic radiation using this material, as well as articles for altering electromagnetic radiation comprising the carbon nanotube containing material.

Due to the electrically insulating properties of most plastics and coatings, electronic equipment incorporating them often has to use conductive fillers to stop electromagnetic interference (EMI) effects. While carbon fibers have often been used for this EMI shielding, they often significantly degrade the overall performance of the final material. In general, the more filler used in a material the lower the performance of the resultant coating. Accordingly, the less material that is used as the EMI shield the higher performance of the resultant material. Conversely, the higher the loading of the carbon nanotubes in the plastic or coating, the greater the EMI shielding effect.

Further, it is desirable to create thinner materials for such portable electronics as cell phones, stereos, computers, and other devices commonly carried out. The thinner the material used in such applications, the less weight the device has. And the lower the weight of the portable electronic, the more useful it is.

One promise of nanotechnology materials is that they will help do things more cost-effectively than their traditional counterparts. In the area of electromagnetic wave management, any technology that can lower the overall cost, simplify a process, and improve efficiencies would be advantageous. Thus, using carbon nanotubes as an additive could significantly improve both the EMI shielding properties as well as physical strength of the resultant material, while diminishing the size and weight of the final product.

Existing management processes would be improved by using optically enhanced nanostructured material. Such enhancements would be useful, for example, to protect personnel, equipment, vehicles, and containers, from the adverse consequences of electromagnetic waves or energy, or detection by interrogation signals. Further advantages of using a nanostructured material include the reduction of weight, increased strength and the rapid distribution of electromagnetic waves.

One type of nanostructured material, carbon nanotubes, have garnered a lot of interest because of its broad range of properties. Carbon nanotubes are generally described as a graphite sheet rolled up into a nanoscale tube form to produce single-wall carbon nanotubes. Alternatively, carbon nanotubes may contain additional graphite tubes around the core of a single walled carbon nanotube to form multi-wall carbon nanotubes.

Some properties associated with carbon nanotubes include high electrical conductivity, high thermal conductivity and stability, optical transmission, electromagnetic absorptivity and strength. These properties make carbon nanotubes very attractive for a variety of potential applications that currently use inferior materials.

For example, the process for shielding or protecting objects from adverse affects of x-ray electromagnetic waves or energy is presently accomplished through the use of highly adsorptive, and heavy materials such as lead.

In addition, the process to intensify an electromagnetic wave or signal varies depending upon the wavelength which is to be intensified. For example, the process for intensifying radio signal involves the amplification of such signals. When intensifying energy in the visible spectrum a metastable gas, as in a laser, may be used.

Similarly, the process to mitigate an electromagnetic wave or signal varies depending upon the wavelength which is to be mitigated. For example, to mitigate a radio signal without back reflection generally requires the use of large carbon fibers fabricated into a cardboard like material matching the index of refraction of a material with that of free space.

As can be seen, the manipulation of electromagnetic energy and/or wavelengths is presently accomplished by a variety of methods and materials, depending on the energy to be manipulated.

It would be beneficial to have a material capable of manipulating, whether mitigating or intensifying, electromagnetic energy and/or wavelengths across the full electromagnetic spectrum. Ideally, such material would have minimal energy requirements, extended life time, greater operating range across larger wavelength, and be lighter weight than currently available material.

### SUMMARY OF INVENTION

The present disclosure addresses the aforementioned issues as they relate to manipulation or control of electromagnetic waves with nanotechnology materials. Accordingly, there is disclosed a material for altering electromagnetic radiation incident on the material. The material comprises carbon nanotubes having a length (L) that meets formula (1):

L≧½ λ (1)

where, λ is the wavelength of the electromagnetic radiation incident on the material. Nanotubes described herein generally have an average diameter in the inclusive range of from 1-60 nm and an average length in the inclusive range of from 0.1 μm to 250 mm.

Also disclosed herein are methods of modifying electromagnetic radiation using the above-described material. Such methods include a method of intensifying electromagnetic radiation by increasing the amount of photons emitted at a specific frequency or wavelength, or a method of absorbing electromagnetic radiation incident on a material and re-transmitting the radiation with frequency and phase coherency.

When the material is used to shield or redirect wavelengths in the x-ray spectrum from penetrating the material, a unique signature management and radiation protective material is created.

When the material is used to shield or redirect wavelengths in the infrared spectrum from penetration and response from the material, a unique signature management, and radiation protective material is created. This method presents a unique cloaking capability from infrared weapon target acquisition technology.

In addition, when a material is coated or applied to the exterior of vehicles or aircraft a unique signature management, and radiation protective material that will shield or redirect wavelengths in the full electromagnetic spectrum from penetration and response from the material is created. This method presents a unique cloaking capability from weapon target acquisition technology.

### DETAILED DESCRIPTION OF THE INVENTION

In one embodiment, the disclosure relates to using carbon nanotube fabricated in a nanostructured or mesh form (NanoMesh) as an EMI shielding membrane. A mesh of carbon nanotubes absorbs electromagnetic radiation at varying wavelengths and frequencies, and will convert this absorbed energy into other forms of energy. As an example, it could absorb visible light and convert the absorbed energy into electricity making an attractive solar cell. Alternatively, it could absorb visible light in one frequency and transfer it to another frequency altogether.

Carbon nanotube mesh (NanoMesh) is a novel material that is composed mostly of carbon nanotubes (either single or multiwalled) that are held together by van der Waals forces, other proximity effects, and mechanical means. It also may have proprietary modifications done to fuse the material together, glue carbon nanotubes to each other, or other processes to make the final material stronger or more EMI shielding.

Unlike Nanomesh, which implies coupling of nanotubes to form a three-dimensional structure, a nanostructured material generally implies carbon nanotubes that are decoupled or not necessarily in contact with one another. In certain embodiments, a nanostructured material may be used instead of a nanomesh material.

As used herein the term “fused,” “fusion,” or any version of the word “fuse” is defined as the bonding of nanotubes at their point or points of contact. For example, such bonding can be Carbon-Carbon chemical bonding including sp³ hybridization or chemical bonding of carbon to other atoms.

Non-limiting examples of how such fused nanostructured material are made can be found in co-pending U.S. patent application Ser. No. 10/859,346, entitled “Fused Nanostructured Material,” filed Jun. 3, 2004, which is herein incorporated by reference.

The incorporation of NanoMesh also makes a material highly strong, durable, and chemically resistant. Thus, materials incorporating the NanoMesh will also be able to be cast extremely thin and still maintain their durability.

In one embodiment, the nanomesh material may comprise carbon nanotubes having a length (L) that meets formula (1):

L≧½ λ (1)

where, A is the wavelength of the electromagnetic radiation incident on the material.

As used herein, “electromagnetic radiation” includes the entire energy spectrum, from very short, high energy gamma particles (0.003 nm to 0.03 nm) to very long radio waves (30 cm to 3 km), and every energy spectrum in-between. For example, electromagnetic spectrum is meant to also encompass X-ray radiation (0.03 nm to 3.0 nm), Ultra-violet radiation (3.0 to 300 nm), the complete visible spectrum (400 nm to 750 nm), Infra-red energy (1 μm to 100 μm), and microwave energy (1 mm to 30 cm). Therefore, in formula (1), λ can include any of these ranges, individually or in combination.

In one embodiment, the ability of the material to alter electromagnetic radiation is enhanced by the use of defective carbon nanotubes. “Defective carbon nanotubes” are those carbon nanotubes distorted by crystalline defects in at least one carbon ring to a degree that a portion of the nanotube between the opposing ends thereof has greater chemical activity at said portion.

Crystalline defects may contain a lattice distortion in at least one carbon ring. A lattice distortion means any distortion of the crystal lattice of carbon nanotube atoms forming the tubular sheet structure. Non-limiting examples include any displacements of atoms because of inelastic deformation, or presence of 5 and/or 7 member carbon rings, or chemical interaction followed by change in sp² hybridization of carbon atom bonds

Examples of how such carbon nanotubes are distorted and how nano-structures which may be useful to the make the material described herein can be found in co-pending U.S. patent application Ser. No. 10/794,056, filed Mar. 8, 2004, and U.S. patent application Ser. No. 10/859,346, filed Jun. 3, 2004, both of which are herein incorporated by reference in their entirety.

In one non-limiting embodiment, the carbon nanotubes which may be useful to alter electromagnetic radiation are chosen from impregnated, functionalized, doped, charged, coated, irradiated, or combinations of such nanotubes.

“Chosen from” or “selected from” as used herein refers to selection of individual components or the combination of two (or more) components. For example, the carbon nanotubes used in the material described herein may comprise any one of impregnated, functionalized, doped, charged, coated, or irradiated, nanotubes or any combination thereof, including all of the foregoing.

In another embodiment, the carbon nanotubes have at least one end which is at least partially open.

The material described herein may further comprising a liquid, solid, or gaseous medium in which the carbon nanotubes are maintained. The carbon nanotubes may be maintained in the medium by a mechanical force or a field chosen from, electromagnetic, acoustic, and optic fields or combinations thereof.

The solid medium in which the carbon nanotubes may be maintained is chosen from at least one metallic, ceramic, or polymeric material. This medium is generally used when an article comprising the inventive material is fabricated.

One method described herein relates to impregnating a fused NanoMesh with polymer to create an entire filled membrane that is durable, strong, and provides EMI shielding. The polymeric material used for filling such a membrane may be chosen from a variety of natural or synthetic polymeric resins. In one non-limiting embodiment, the polymeric material may comprise at least one polymer chosen from thermoplastics, thermosetting polymers, elastomers and combinations thereof.

In other non-limiting embodiments, the polymeric may be chosen from, nylon, polyurethane, acrylic, methacrylic, polycarbonate, epoxy, silicone rubbers, natural rubbers, synthetic rubbers, vulcanized rubbers, polystyrene, aramid, polyethylene, ultra-high-molecular weight polyethylene, high-density polyethylene (HDPE), low-density polyethylene (LDPE), poly(p-fenyl-2, 6-benzobisoxazol), polypropylene, polychloroprene, polyimide, polyamide, polyacrylonitrile, polyhydroaminoester, polyester (polyethylene terephthalate), polybutylene terephthalate, poly-paraphylene terephtalamide, polyester ester ketene, fluoropolymers, including viton fluoroelastomer, polytetrafluoroethylene, and polyvinylchloride, polyesters, polyethers, polyacrylates, polysulfides, acrylonitriles, cellulose, gelatin, chitin, polypeptides, polysaccharides, polynucleotides and mixtures thereof.

The polymeric material may further comprise a material chosen from ceramic hybrid polymers, phosphine oxides and chalcogenides. Examples of the above-mentioned polymers can be found in United States Published Patent Application No. 20030164427, filed Sep. 4, 2003, which is herein incorporated by reference.

In one embodiment, the multi-component polymers may exhibit at least two different glass transition or melting temperatures. As used herein, “glass transition temperature” (T_{g}) is defined as the transition from the liquid state to the glassy state, at a temperature below the equilibrium melting point of the material. T_{g} is usually applicable to amorphous phases in both glasses and plastics. In its simplest sense, T_{g} is the temperature below which molecules have very little mobility. For example, in polymers, T_{g} is the temperature at which an amorphous polymer (or the amorphous regions in a partially crystalline polymer) changes from a hard and relatively brittle condition to a viscous or rubbery condition.

In polymers, T_{g} is often expressed as the temperature at which the Gibbs free energy is such that the activation energy for the cooperative movement of about 50 elements of the polymer is exceeded. This allows molecular chains to slide past each other when a force is applied.

In glasses, as well as amorphous metals and gels, T_{g} is related to the energy required to break and re-form covalent bonds. The T_{g} is therefore influenced by the chemistry of the glass. For example, the addition of elements having a valency less than 4, such as B, Na, K or Ca to a silica glass, help break up the three-dimensional lattice and reduce the T_{g}. Conversely, the addition of an element having a valency of 5, such as P, helps re-establish the three-dimensional lattice, thus increasing T_{g}.

From a practical point of view, the glass transition temperature is defined empirically as the temperature at which the viscosity of the liquid exceeds a certain value (commonly 10¹³ Pascal-seconds). The transition temperature depends on cooling rate, with the glass transition occurring at higher temperatures for faster cooling rates.

In another embodiment, a fused NanoMesh material may be filled with a ceramic, including a glass such as fiberglass, flat glass, and/or others known in the art. Alternatively, the glass could be physically mixed with the NanoMesh instead of impregnation. Such a ceramic/glass-based nanomesh material could be used in corporate and government boardrooms to prevent eaves dropping, electronic noise and the like.

Typical ceramic materials that may be used herein include at least one of the following: boron carbide, boron nitride, boron oxide, boron phosphate, spinel, garnet, lanthanum fluoride, calcium fluoride, silicon carbide, carbon and its allotropes, silicon oxide, glass, quartz, aluminum oxide, aluminum nitride, zirconium oxide, zirconium carbide, zirconium boride, zirconium nitride, hafnium boride, thorium oxide, yttrium oxide, magnesium oxide, phosphorus oxide, cordierite, mullite, silicon nitride, ferrite, sapphire, steatite, titanium carbide, titanium nitride, titanium boride, and combinations thereof.

Typical metallic materials that may be used herein include at least one of the following: aluminum, boron, copper, cobalt, gold, platinum, silicon, steel, titanium, rhodium, indium, iron, palladium, germanium, tin, lead, tungsten, niobium, molybdenum, nickel, silver, zirconium, yttrium, and alloys thereof.

In one embodiment, the liquid medium in which the nanotubes may be found comprises water, oils, organic solvents, inorganic solvents, the liquid form of nitrogen, or the liquid form of carbon dioxide.

The gaseous medium in which the nanotubes may be found comprises the air, or a gas chosen from argon, nitrogen, helium, ammonia, and carbon dioxide.

The carbon nanotubes described herein may be single-walled, multi-walled, nanoscrolled or combinations thereof. In addition, the carbon nanotubes may take a variety of known morphologies, such as those chosen from nanohoms, cylinders, nanospirals, dendrites, spider nanotube structures, Y-junction nanotubes, nanorods, and bamboo morphology.

The above described nanotube shapes are more particularly defined in M. S. Dresselhaus, G. Dresselhaus, and P. Avouris, eds. Carbon Nanotubes: Synthesis, Structure, Properties, and Applications, Topics in Applied Physics. Vol. 80. 2000, Springer-Verlag; and “A Chemical Route to Carbon Nanoscrolls, Lisa M. Viculis, Julia J. Mack, and Richard B. Kaner; Science 28 Feb. 2003; 299, both of which are herein incorporated by reference.

In one embodiment, the carbon nanotubes may be functionalized with one or more inorganic or organic compounds attached to the surface of the carbon nanotubes. The carbon nanotubes described herein may be derivatized or functionalized with various agents. Non-limiting examples of agents that can be functionalized unto carbon nanotubes and methods of functionalization can be found in United States Published Patent Application No. 20020102196, filed Aug. 1, 2002, which is herein incorporated by reference.

For example, organic compounds which may be functionalized onto the surface of the carbon nanotubes include at least one chemical group chosen from carboxyls, amines, polyamides, polyamphiphiles, diazonium salts, pyrenyls, silanes, dyes, quantum dots and combinations thereof.

As used herein, “quantum dots” are defined as nanoparticles that absorbs energy at one wavelength and emits it at another wavelength. Typically, quantum dots comprise nanometer-sized semiconductor crystals. Because such objects are so small, adding or removing a single electron represents a significant change in energy. In certain embodiments, these nano-scale crystalline structures can transform the color of light. Quantum dots are considered to have greater flexbility than other fluorescent materials, which makes them suited to use in building nano-scale computing applications where light is used to process information. They can made from a variety of different compounds, such as cadmium selenide. In one embodiment, quantum dots comprise one or more layers of metal.

Inorganic compounds which may be functionalized onto the surface of the carbon nanotubes include at least one at least one halogenated compound of boron, titanium, niobium, tungsten, and combination thereof. In one embodiment, the halogenated compound comprises fluorine.

It is possible that both the inorganic or organic compounds are located on the ends of the carbon nanotubes and are optionally polymerized. When the end caps of the carbon nanotubes have functional derivatives, it is possible to assemble achieve greater chemical activity at the ends of the carbon nanotubes, or to create a three-dimensional structure in a head-to-tail fashion. Alternatively, functional derivatives may be located at any location along the carbon nanotubes. In this manner, it is possible to create a non-uniformity in composition and/or density of functional groups (and thus properties) across the surface of the carbon nanotubes and/or across at least one dimension of the material.

In another embodiment, it is possible that the functionalized carbon nanotubes comprise a substantially uniform gradient of functional groups across the surface of the carbon nanotubes and/or across at least one dimension of the material.

Typical metallic materials which may be used to coat the carbon nanotubes include at least one metal chosen from gold, platinum, titanium, rhodium, iridium, indium, copper, iron, palladium, gallium, germanium, tin, lead, tungsten, niobium, molybdenum, silver, nickel, cobalt, metals of the lanthanum group, metals of the actinide group, and alloys thereof.

Typical polymeric polymeric materials that may be used to coat the carbon nanotubes are the same polymers as those previously described.

As used herein, a “doped” carbon nanotube refers to the presence of atoms, other than carbon, in the nanostructured material.

With respect to impregnation, a photon specific device composed of a target ion- impregnated carbon nanotube can be fabricated. For this device, the impregnated nanotubes can be fabricated such that an electron or phonon current can either be induced by electromagnetic, or acoustic means or by direct electrical or physical connection, and have defect sites that can be opened through functionalization chemistry to create ion channels.

The electron structure of the material can be tailored by doping filling impregnating or functionalizing the nanotubes to serve particular applications. For example, quantum wells may be created within the hollow region of the nanotube due to the quasi-one dimensional nature of the carbon nanotube defined by its morphology. This will create a “pre-programmed” or reprogrammable optical response ion specific trap when the ion is moved or indexed through the carbon nanotube. When the ion is moved within the nanotube, the ion specific trap is left behind, in the quasi one-dimensional quantum structure of the nanotube.

As photons or electromagnetic waves comes into contact with the treated “pre-programmed” nanostructured material containing the target ions, the target ion will be able to minimize its free energy by adsorbing and filling the ion specific trap within the nanotube. The addition of the target ion in the nanotube will cause a change in resistance, which will trigger an electric and/or phononic current response that will move at least one ion through the nanotube and out of the system. The material can be programmed or reprogrammed depending on what ion the nanotube, nanostructured device has been filled with.

Depending on the needed optical response the target material or the material that is used to impregnate, functionalize, dope, fill or coat the carbon nanotubes may comprise at least one compound chosen from oxygen, hydrogen, ionic compounds, halogenated compounds, sugars, alcohols, peptides, amino acids, RNA, DNA, endotoxins, metalo-organic compounds, oxides, borides, carbides, nitrides, and elemental metals and alloys thereof in an amount sufficient to achieve a desired effect.

In one embodiment, the carbon nanotubes exhibit an absorption efficiency for electromagnetic radiation up to and including 100%, wherein the absorption efficiency is related to the cos σ. In this embodiment, σ is the angle of the incoming electromagnetic radiation incident on the nanotubes, σ having a value ranging from 0 to 90°, as measured from the axis perpendicular to the nanotube. For example, in one embodiment, the absorption efficiency is 100% when a equals 90°.

When the carbon nanotubes are functionalized or coated with a fluorescent material, it is typically in an amount sufficient to re-radiate electromagnetic energy with different directional properties than that of the incident radiation, thus changing the luminosity of the material. In its simplest form, “different directional properties” means that the re-radiated electromagnetic energy is transmitted at different angles than the incident radiation.

By functionalizing the material described herein with a fluorescent material, the wavelength of re-radiated electromagnetic energy is altered. In one embodiment, for example, the luminosity of the material is increased by functionalizing or coating the carbon nanotubes with materials that have the property of absorbing energy at one wavelength and re-transmitting it at a lower wavelength. This property is commonly known “fluorescence.”

In one embodiment, by functionalizing, one skilled in the art would understand that one or more inorganic compounds attached to the surface of the carbon nanotubes comprise additional carbon nanotubes.

In another embodiment, functionalizing the carbon nanotubes comprises chemically attaching at least one dye molecule to the carbon nanotubes. Typical dyes that can be used herein are found, for example, in “Industrial Dyes Chemistry, Properties, Applications,” (Klaus Hunger editor); and “Color Chemistry: Syntheses, Properties and Applications of Organic Dyes and Pigments,” 2^{nd} Edition, by Heinrich Zollinger, both of which are herein incorporated by reference.

In yet another embodiment, functionalizing the carbon nanotubes comprises bringing quantum dots into contact with or adjacent to the carbon nanotubes.

The material described herein is useful in any application where altering electromagnetic radiation is desirable. “Altering electromagnetic radiation” means any disruption or re-transmission of electromagnetic radiation. For example, it may comprise absorbing electromagnetic radiation incident on the material and re-transmitting the radiation with frequency and phase coherency.

One skilled in the art would appreciate the numerous methods in which this material may be used. For example, in its simplest sense, the material described herein may be used to modify electromagnetic radiation, by a method that simply comprises illuminating the previously described material with electromagnetic radiation.

In another embodiment, a method of intensifying electromagnetic radiation by increasing the amount of photons emitted at a specific frequency or wavelength may be carried out using the inventive material. This method comprises contacting electromagnetic radiation with a material comprising carbon nanotubes that are functionalized or coated with at least one fluorescent material. The at least one fluorescent material transforms light energy incident on the material into electrical energy at the specific frequency or wavelength.

By functionalizing the material described herein with a fluorescent material, the wavelength of re-radiated electromagnetic energy is altered. In one embodiment, for example, the luminosity of the material is increased by functionalizing or coating the carbon nanotubes with materials that have the property of absorbing energy at one wavelength and re-transmitting it at a lower wavelength. This property is commonly known “fluorescence.”

In one embodiment, the fluorescent material comprises the previously mentioned dyes.

In one embodiment, altering electromagnetic radiation comprises absorbing electromagnetic radiation incident on the material and re-transmitting it with frequency and phase coherency. In this is effect, which is known as lasing, the nanotube is using the incident radiation to stimulate emission, much the same way a laser generates phase coherent light.

Also described herein is an article comprising the above material. In one embodiment, the article comprises an electronic device, such as portable electronic devices chosen from cell phones, laptop computers, CD players, MP3 players, camcorders, handheld computers, and cordless telephones. The electronic device may also be chosen from audio and video devices for the home, audio and video devices for vehicles or airplanes, telephones, and computers.

In another embodiment, the article may comprise energy absorbing glass that is optically transparent. Such energy absorbing glass is typically found in a building or vehicle, such as automobiles, aircrafts, boats, subways, and rail cars.

In yet another embodiment, the article may comprise at least a portion of the exterior of an airplane, tank, missile or military vehicle.

Particle size of the previously describe nanomaterials is determined by a number distribution, e.g., by the number of particles having a particular size. The method is typically measured by microscopic techniques, such as by a calibrated optical microscope, by calibrated polystyrene beads and by calibrated scanning force microscope or scanning electron microscope or scanning tunneling microscope and scanning electron microscope. Methods of measuring particles of the sizes described herein are taught in Walter C. McCrone's et al., The Particle Atlas, (An encyclopedia of techniques for small particle identification), Vol. I, Principles and Techniques, Ed. Two (Ann Arbor Science Pub.), which is herein incorporated by reference.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention.

1. A material for altering electromagnetic radiation incident on the material, said material comprising carbon nanotubes having a length (L) that meets the following formula (1):
L≧½ λ (1)
where,
λ is the wavelength of the electromagnetic radiation incident on the material.

2. The material of claim 1, wherein the carbon nanotubes are distorted by crystalline defects in at least one carbon ring to a degree that a portion of the nanotube between the opposing ends thereof has greater chemical activity at said portion.

3. The material of claim 2, wherein the carbon nanotubes are impregnated, functionalized, doped, charged, coated, irradiated, or combinations thereof.

4. (canceled)

5. The material of claim 1, further comprising a solid medium in which the carbon nanotubes are maintained.

6. (canceled)

7. The material of claim 5, wherein the solid medium comprises at least one ceramic, or polymeric material.

8. The material of claim 7, wherein the carbon nanotubes are fused together to form a nanomesh, and the polymeric material is used to impregnate the nanomesh, said polymeric material comprising single or multi-component polymers chosen from nylon, polyurethane, acrylic, methacrylic, polycarbonate, epoxy, silicone rubbers, natural rubbers, synthetic rubbers, vulcanized rubbers, polystyrene, aramid, polyethylene, ultra-high-molecular weight polyethylene, high-density polyethylene (HDPE), low-density polyethylene (LDPE), poly(p-fenyl-2, 6-benzobisoxazol), polypropylene, polychloroprene, polyimide, polyamide, polyacrylonitrile, polyhydroaminoester, polyester (polyethylene terephthalate), polybutylene terephthalate, poly-paraphylene terephtalamide, polyester ester ketene, viton fluoroelastomer, polytetrafluoroethylene, and polyvinylchloride, polyesters, polyethers, polyacrylates, polysulfides, acrylonitriles, cellulose, gelatin, chitin, polypeptides, polysaccharides, polynucleotides and mixtures thereof.

9. (canceled)

10. The material of claim 7, wherein the ceramic material is chosen from at least one of the following: boron carbide, boron nitride, boron oxide, boron phosphate, spinel, garnet, lanthanum fluoride, calcium fluoride, silicon carbide, carbon and its allotropes, silicon oxide, glass, quartz, aluminum oxide, aluminum nitride, zirconium oxide, zirconium carbide, zirconium boride, zirconium nitride, hafnium boride, thorium oxide, yttrium oxide, magnesium oxide, phosphorus oxide, cordierite, mullite, silicon nitride, ferrite, sapphire, steatite, titanium carbide, titanium nitride, titanium boride, and combinations thereof.

11-13. (canceled)

14. The material of claim 1, wherein the carbon nanotubes are single-walled, multi-walled, nanoscrolled or combinations thereof.

15. (canceled)

16. The material of claim 1, wherein the carbon nanotubes are functionalized with one or more inorganic or organic compounds attached to the surface of the carbon nanotubes.

17-21. (canceled)

22. The material of claim 16, wherein the functionalized carbon nanotubes comprise a non-uniformity in composition and/or density of functional groups across the surface of the carbon nanotubes and/or across at least one dimension of the material.

23. The material of claim 16, wherein the functionalized carbon nanotubes comprise a substantially uniform gradient of functional groups across the surface of the carbon nanotubes and/or across at least one dimension of the material.

24. The material of claim 1, wherein the carbon nanotubes are coated with one or more metallic or polymeric materials.

25-28. (canceled)

29. The material of claim 1, wherein said carbon nanotubes are functionalized or coated with a fluorescent material, said fluorescent material being in an amount sufficient to re-radiate electromagnetic energy with different directional properties than that of the incident radiation, thus changing the luminosity of the material.

30-32. (canceled)

33. The material of claim 1, wherein altering electromagnetic radiation comprises absorbing electromagnetic radiation incident on the material and re-transmitting said radiation with frequency and phase coherency.

34-40. (canceled)

41. An article comprising the material of claim 1.

42. The article of claim 41, comprising an electronic device.

43-44. (canceled)

45. The article of claim 41, wherein said article comprises energy absorbing glass that is optically transparent.

46. (canceled)

47. The article of claim 41, said article comprising at least a portion of the exterior of an airplane, tank, missile or military vehicle.

48. (canceled)

49. A method of intensifying electromagnetic radiation by increasing the amount of photons emitted at a specific frequency or wavelength,
said method comprising contacting electromagnetic radiation with a material comprising carbon nanotubes that are functionalized or coated with at least one fluorescent material,
said carbon nanotubes having a length (L) that meets the following formula (1):
L≧½ λ (1)
where
λ is the wavelength of the electromagnetic radiation incident on the material.
wherein the at least one fluorescent material transforms light energy incident on the material into electrical energy at the specific frequency or wavelength.

50. A method of absorbing electromagnetic radiation incident on a material and retransmitting said radiation with frequency and phase coherency,
said method comprising contacting electromagnetic radiation with a material comprising carbon nanotubes having a length (L) that meets the following formula (1):
L≧½ λ (1)
where,
λ is the wavelength of the electromagnetic radiation incident on the material.
